(19) United States
(12) Patent Application Publication
(10) Pub. No.: US 2016/0282414 A1
(43) Pub. Date: Sep. 29, 2016

(54) BOUNDARY SCAN TESTING WITH LOOPBACKS

(71) Applicant: NetApp, Inc., Sunnyvale, CA (US)

(72) Inventors: Bryan J. Gielarowski, Pittsburgh, PA (US); Hor-Lam Cheuk, Cupertino, CA (US); Richard M. Strong, Pittsburgh, PA (US)

(21) Appl. No.: 14/665,621

(22) Filed: Mar. 23, 2015

(51) Int. Cl. G01R 31/317; G01R 31/3177

(52) U.S. Cl. CPC G01R 31/31723; G01R 31/3177

(57) ABSTRACT

JTAG testing can be facilitated by providing loopbacks in a circuit that lacks a JTAG interface. A loopback may be created by connecting a receiving pin to a transmit pin of a circuit that lacks the JTAG interface. The loopback would cause a test value received in the circuit to be transmitted back out of the circuit. Therefore, a test value may be sent from an integrated circuit with a JTAG interface and then read back at the same integrated circuit with the JTAG interface. Using a loopback allows the interconnects between two integrated circuits to be tested despite one integrated circuit lacking a JTAG interface. Using the loopback also frees up pins for one of the integrated circuits that would otherwise be used by the JTAG interface.

### BACKGROUND

This disclosure generally relates to the field of computer systems, and, more particularly, to the testing of electrical devices.

During the manufacturing of printed circuit boards (“PCBs”), testing is performed to ensure that all interconnects within the PCB are functioning properly. Often, additional circuitry is added to the PCB and integrated circuits on the PCB to enable boundary scan testing. Boundary scan allows for testing interconnects between two or more integrated circuits on the PCB. During boundary scan testing, the functionality of a pin in an integrated circuit is overridden and a test value is driven to the pin and over the individual interconnect connected to the pin. The test value is then read at the destination pin of another integrated circuit and compared to the original test value to determine if there is any fault in the interconnect. One method of performing boundary scan testing is specified by the IEEE 1149.1 standard entitled “Standard Test Access Port and Boundary-Scan Architecture.” This standard is commonly referred to as JTAG, which is the acronym for the group (Joint Test Action Group) that developed the standard.

JTAG provides for a special interface and control logic added to integrated circuits that allows for testing and debugging of a board as described above. A JTAG interface typically includes control logic and four pins: test data in (“TDI”), test data out (“TDO”), test clock (“TCK”), and test mode select (“TMS”). The control logic typically includes a Test Access Port (“TAP”) controller, which is controlled by the TMS and TCK pins. Additionally, an integrated circuit with a JTAG interface will include boundary scan architecture. The boundary scan architecture includes a boundary scan cell located at each pin of the integrated circuit. The JTAG interface is used to shift in test values to registers in the boundary scan cells. The test values in the boundary scan cell registers are then applied to the pins and may be used to test interconnects in the board.

### SUMMARY

JTAG testing can be facilitated by providing loopbacks in a circuit that lacks a JTAG interface. A loopback may be created by connecting a receiving pin to a transmit pin of a circuit that lacks the JTAG interface. The loopback would cause a test value received in the circuit to be transmitted back out of the circuit. Therefore, a test value may be sent from an integrated circuit with a JTAG interface and then read back at the same integrated circuit with the JTAG interface. Using a loopback allows the interconnects between two integrated circuits to be tested despite one integrated circuit lacking a JTAG interface. Using the loopback also frees up pins for one of the integrated circuits that would otherwise be used by the JTAG interface.

This summary is to be used as a brief summary for the disclosure, and not a comprehensive summary. The purpose of the brief summary is to provide a compact explanation that helps in understanding the disclosure. This brief summary does not capture the entire disclosure, and should not be used limit claim scope.

### BRIEF DESCRIPTION OF THE DRAWINGS

The disclosures herein may be better understood by referencing the accompanying drawings.

FIG. 1 is a conceptual diagram illustrating the testing of interconnects between integrated circuits using a loopback.

FIG. 2 depicts a flow diagram illustrating example operations for performing JTAG testing using a loopback in a non-JTAG device.

FIG. 3 is a conceptual diagram illustrating the testing of interconnects between integrated circuits using multiple loopbacks.

FIG. 4 depicts a flow diagram illustrating example operations for performing a JTAG test using multiple loopbacks in a non-JTAG device.

FIG. 5 is a conceptual diagram illustrating the testing of interconnects between multiple integrated circuits using loopbacks.

FIG. 6 is a conceptual diagram illustrating the differential signaling testing of interconnects between integrated circuits using loopbacks.

FIG. 7 is a conceptual diagram illustrating the testing of interconnects between integrated circuits using a loopback integrated in a printed circuit board

### DETAILED DESCRIPTION

The description that follows includes example systems, methods, techniques, and machine instructions/program code that embody techniques of the disclosure. However, it is understood that the described aspects may be practiced without these specific details. For instance, although examples refer to loopbacks incorporated within an integrated circuit, loopbacks may be incorporated within a printed circuit board. In other instances, well-known instruction instances, structures and techniques have not been shown in detail in order not to obfuscate the description.

Introduction

A PCB contains a number of interconnects that flow within the board to connect the pins of various components or integrated circuits. To ensure proper functionality of the system, each interconnect is tested for proper functionality. Testing each interconnect manually by placing a probe at the start and destination pins of an interconnect or using a bed-of-nails setup is not always feasible given the number of connections on a board and the fact that integrated circuits often have pins that are not readily accessible, such as when the circuits are seated using a ball grid array. To overcome this problem, a JTAG interface is built into integrated circuits to allow for testing and debugging. For example, when two integrated circuits have a JTAG interface, the JTAG interface of a first integrated circuit can be used to shift a test value to a desired pin which can be read at the TDO pin of a second integrated circuit. However, an integrated circuit may not have any spare pins to accommodate the JTAG interface, or providing the interface and control logic may be undesirable due to costs or size constraints. If the second integrated circuit lacks a JTAG interface, reading the test value may require manually applying a test probe. Since the test value cannot be verified, the functionality of the interconnects between the first integrated circuit and the second integrated circuit cannot be confirmed.

Overview

JTAG testing can be facilitated by providing loopbacks in a circuit that lacks a JTAG interface. A loopback may be created by connecting a receiving pin to a transmit pin of a circuit that lacks the JTAG interface. The loopback would cause a test value received in the circuit to be transmitted back out of the circuit. Therefore, a test value may be sent from an integrated circuit with a JTAG interface and then read back at the same integrated circuit with the JTAG interface. Using a loopback allows the interconnects between two integrated circuits to be tested despite one integrated circuit lacking a JTAG interface. Using the loopback also frees up pins for one of the integrated circuits that would otherwise be used by the JTAG interface.

Example Illustrations

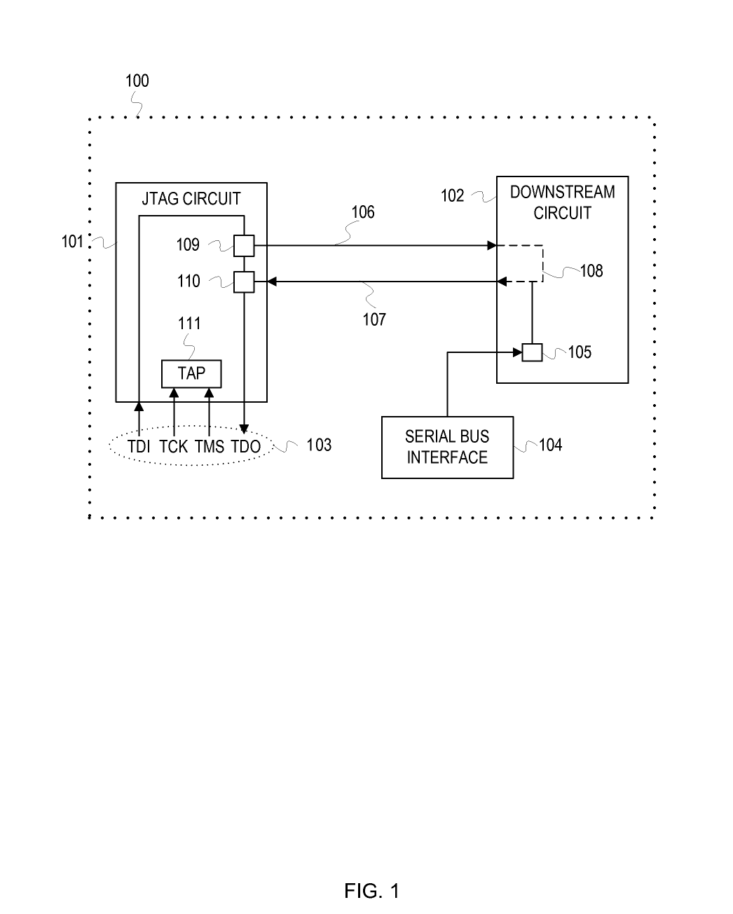

FIG. 1 is a conceptual diagram illustrating the testing of interconnects between integrated circuits using a loopback. FIG. 1 depicts a printed circuit board 100 that includes a JTAG circuit 101, a downstream circuit 102, and a serial bus interface 104 (“interface 104”). The JTAG circuit 101 is a JTAG capable circuit and includes JTAG pins 103. The JTAG pins 103 include the typical four pins for JTAG testing, TDI, TCK, TMS and TDO, but additional pins in accordance with other JTAG pin configurations may be included, such as the test reset pin, TRST. The TCK and TMS pins of the JTAG pins 103 are connected to a TAP controller 111. The TAP controller 111 includes a state machine and an instruction register, not depicted, in accordance with the IEEE 1149.1 standard. The TAP controller 111 may also include additional circuitry such as a bypass register. The state machine of the TAP controller 111 may be controlled using the TCK and TMS pins of the JTAG pins 103. The JTAG circuit 101 also includes boundary scan architecture including multiple input and output boundary scan cells (“BSC”). To avoid congestion, FIG. 1 only depicts output BSC 109 and input BSC 110. A circuit with boundary scan architecture generally includes a BSC coupled to each pin of the circuit and connected in series between the TDI and TDO pins of the JTAG pins 103. The output BSC 109 and input BSC 110 include the typical circuitry of input and output boundary scan cells. For example, the output BSC 109 includes a register for storage of a test value and circuitry needed to drive a test value. The input BSC 110 includes a register to capture incoming test values. The JTAG circuit 101 and the downstream circuit 102 are connected by interconnects 106 and 107. The downstream circuit 102 includes a loopback 108 and a control register 105 that is accessible to the interface 104.

The JTAG circuit 101 and the downstream circuit 102 may be connected to the board 100 through a direct soldered connection, through a socket such as a land grid array (“LGA”) socket, by surface mounting, through a connector, etc. Additionally, JTAG circuit 101 and the downstream circuit 102 may be any kind of integrated circuit. For example, one of the circuits may be a processor or may be an integrated circuit on a Peripheral Component Interconnect Express (“PCIe”) card that connects to the board 100 through a PCIe interface connector. The board 100 may also contain connected components other than those depicted.

The JTAG circuit 101 and the downstream circuit 102 are electrically connected and able to communicate through the interconnects 106 and 107. The interconnect 106 connects to an output pin of the JTAG circuit 101 that is coupled to the output BSC 109. The interconnect 107 connects to a pin of the JTAG circuit 101 that is coupled to the input BSC 110. The interconnects 106 and 107 are connected with the loopback 108 of the downstream circuit 102 when the loopback 108 is activated. Activating the loopback 108 will be discussed in more detail below.

The JTAG pins 103, the output BSC 109, the input BSC 110, and the TAP controller 111 are used to conduct JTAG testing in accordance with the IEEE 1149.1 standard. The output BSC 109 is used to transmit test values from the JTAG circuit 101 to the downstream circuit 102 during JTAG testing. Using the TAP controller 111, a test value can be shifted in through the TDI pin to the register of the output BSC 109. The test value may then be latched to the pin of the JTAG circuit 101 coupled to the output BSC 109 and transmitted through the interconnect 106 to the downstream circuit 102. The test value continues through the loopback 108 and then through the interconnect 107. The test value is received at the input pin coupled to the input BSC 110. As described in further detail below, the test value as received at the input BSC 110 may be captured and read through the TDO pin of the JTAG pins 103 and compared to the test value originally transmitted by the output BSC 109.

The loopback 108 may be activated using the interface 104 to set the control register 105 to the appropriate value. For example, the path of loopback 108 may contain a transistor coupled to the control register 105 causing the transistor to act like a switch. Setting the control register 105 to a value “0” would turn the transistor “off”, deactivate the loopback 108, and allow the downstream circuit 102 to function normally. Setting the control register 105 to a value “1” would turn the transistor “on” and activate the loopback 108 for testing. Additionally, a demultiplexer may be used to select whether the incoming test value is sent to the core logic of the downstream circuit 102 or through the loopback 108.

Activating the loopback 108 causes the test value to bypass the downstream circuit 102 core logic by directly connecting the interconnect 106 to the interconnect 107. Therefore, assuming the interconnects 106 and 107 are functioning properly, the same test value transmitted by the output BSC 109 will be received by the input BSC 110. If the test value is different, then the difference indicates that at least one of the interconnect 106 and the interconnect 107 contains a fault such as a short, an open, or other fault.

The interface 104 may be any type of interface that allows communication with components on the board 100 and is capable of changing the value of control register 105. For example, the I²C serial bus interface may be used. The interface 104 may be a separate component on the board 100 or may be a component on a board with the downstream circuit 102. For example, if the downstream circuit 102 is on a PCIe card, the interface 104 may also be located on the PCIe card.

The interconnects 106 and 107 may be etched or printed connections, such as traces, or may be conductive wire connecting the JTAG circuit 101 and the downstream circuit 102.

As depicted in FIG. 1, the JTAG circuit 101 and downstream circuit 102 communicate using single ended signaling through a single input pin and output pin in each circuit. In some instances, the JTAG circuit 101 and downstream circuit 102 may communicate through a number of input and output pins. For example, the JTAG circuit 101 and the downstream circuit 102 may communicate using two input pins and two output pins. In this instance, a separate loopback could be used to connect each of the two sets of input and output pins. The two loopbacks allow JTAG testing to be conducted with two test values being transmitted and received.

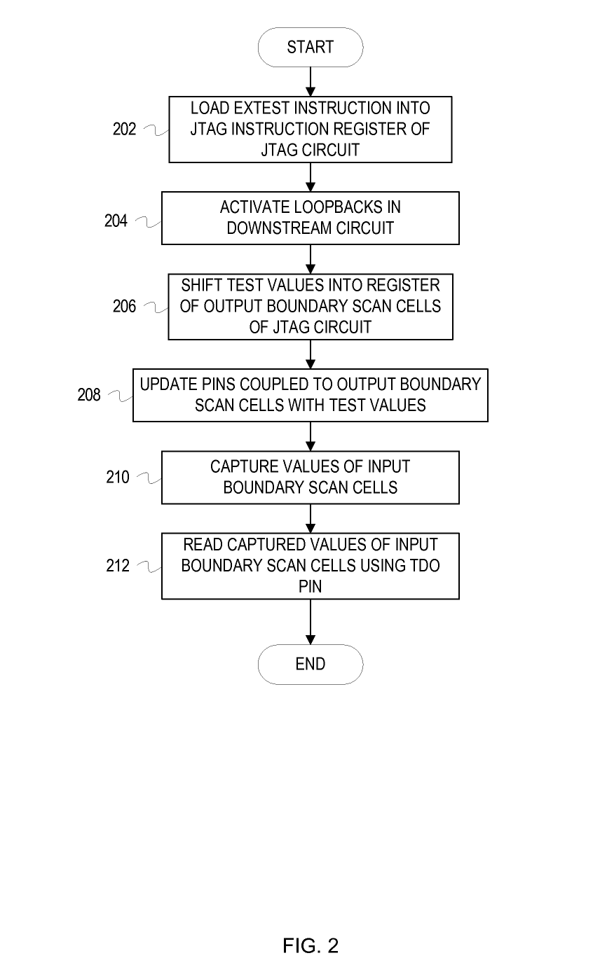

FIG. 2 depicts a flow diagram illustrating example operations for performing JTAG testing using a loopback in a non-JTAG device.

At block 202, the EXTEST JTAG instruction is loaded into a JTAG instruction register of a JTAG circuit. The EXTEST instruction is defined in the IEEE 1149.1 standard and is used for interconnect testing. The EXTEST instruction allows for test values to be set on pins coupled to boundary scan cells without interference from the core logic of the JTAG circuit. Once the EXTEST instruction has been loaded into the instruction register, control then flows to block 204.

At block 204, loopbacks in a downstream circuit are activated. Loopbacks in the downstream circuit connect the input or receive pins of the downstream circuit to the output or transmit pins of the downstream circuit. The output/transmit pins are connected to the preceding JTAG capable integrated circuit (“JTAG circuit”) that supplied the test values to the input/receive pins. Activating loopbacks in the downstream circuit allows for test values received from a JTAG circuit on the input pins to be transmitted through the output pins. The test values are transmitted from the downstream circuit to input pins of the JTAG circuit. The JTAG circuit and downstream circuit may communicate using multiple input and output pins or channels. For example, the JTAG circuit may have two output pins connected to two input pins of the downstream circuit and two input pins connected to two output pins of the downstream circuit. A separate loopback for each set of input and output pins may be concurrently activated at the downstream circuit to allow for testing of all the interconnects between the JTAG circuit and downstream circuit simultaneously. After the loopbacks are activated, control then flows to block 206.

At block 206, test values are shifted into the registers of the output BSCs of the JTAG circuit. Test values may be shifted into the registers of the output BSCs using the TDI pin and the TAP controller. Using JTAG testing techniques, the state machine of the TAP controller may be controlled using the TCK and TMS pins and placed into a state to allow for shifting incoming test values at the TDI pin to the registers of the BSCs. For example, if there are two output BSCs, a test value sequence of “10” may be input to the TDI pin and shifted in so that the register of a first output BSC is “1” and the register of a second BSC is “0”. After the test values have been shifted into registers, control then flows to block 208.

At block 208, pins of the JTAG circuit coupled to the output BSCs are updated with the test values. The state machine of the TAP controller may be placed into a state to update the pins of the JTAG circuit with the test values found in the registers of the output BSCs. Once updated, each pin coupled to an output BSC drives the test value that was shifted into the output BSC register. For example, if the output BSC register was “1”, the pin coupled to the output BSC would then drive a “1” over the interconnect connected to the pin. Once the pins have been updated with the test values, control then flows to block 210.

At block 210, the values at input pins of the JTAG circuit are captured using input BSCs. Once a test value is driven from an output BSC as described at block 208, the test value will transmit through an interconnect connecting the JTAG circuit and the downstream circuit, transmit through the activated loopback in the downstream circuit, and return through another interconnect to an input pin of the JTAG circuit. The transmitted test value at the input pin may be captured by an input BSC coupled to the input pin of the JTAG circuit. The value is captured from the pin of the JTAG circuit and is stored in the register of the input BSC. The values found at each of the input BSCs may be captured simultaneously by placing the TAP controller into the capture state. The different states of the TAP controller state machine may be traversed using the TCK and TMS pins. The TMS pin controls which state to transition to based on whether the TMS pin has a “1” or “0” value on the rising edge of the TCK clock. Once the test values have been driven to the input pins of the downstream circuit during the update state, the TMS pin may be held to a “0” to traverse to an idle state. The TMS pin may be set to a “1” on a first rising clock edge and then a “0” on a second rising clock edge to traverse to the capture state. Once the test values have been captured, control then flows to block 212.

At block 212, the captured test values are read through the TDO pin. The captured test values are stored in the registers of the input BSCs. By placing the TAP controller into the shift state, the test values may be shifted out of the input BSC registers and read at the TDO pin. Once the captured test values have been read, the captured test values may be compared to the originally transmitted test values to determine whether any faults exist. For example, if a “1” test value was driven from an output BSC but a “0” was received at a corresponding input BSC, then it can be assumed that there is a fault in the set of interconnects in which the test value traveled to and from the JTAG circuit to the downstream circuit. After the captured test values have been read, the process ends.

The example operations described in FIG. 2 may be performed multiple times with different test values shifted into the output BSCs.

In the descriptions above, the JTAG circuit and the downstream circuit are assumed to have an equal number of input pins as compared to output pins between the two circuits. Having an equal number of input and output pins allows for a separate loopback to be used to connect each of the input pins to a separate output pin in the downstream circuit and allows for all of the loopbacks to be activated concurrently. In some instances, a downstream circuit may have two output pins but only one input pin in communication with the JTAG circuit. In such an instance, two loopbacks may be used: a first loopback connecting the input pin to a first output pin and a second loopback connecting the input pin to a second output pin. Since two loopbacks are connected to the same input pin, both loopbacks may not be activated simultaneously during testing. However, each loopback may be activated independently as described below.

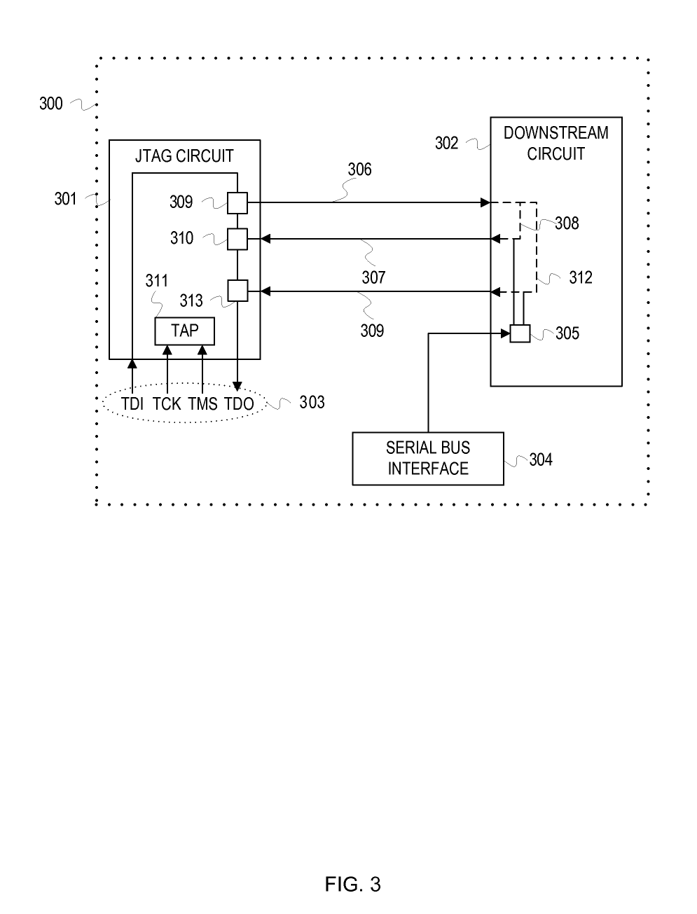

FIG. 3 is a conceptual diagram illustrating the testing of interconnects between integrated circuits using multiple loopbacks. FIG. 3 depicts a printed circuit board 300 that includes a JTAG circuit 301, a downstream circuit 302, and a serial bus interface 304 (“interface 304”). The JTAG circuit 301 is a JTAG capable circuit including JTAG pins 303: TDI, TCK, TMS and TDO. The TCK and TMS pins of the JTAG pins 303 are connected to a TAP controller 311. The JTAG circuit 301 also includes boundary scan architecture including multiple input and output BSCs. As with FIG. 1, FIG. 3 only depicts output BSC 309, input BSC 310, and input BSC 313. The JTAG circuit 301 and the downstream circuit 302 are connected by interconnects 306, 307, and 309. The downstream circuit 302 includes loopback 308, loopback 312, and a control register 305 that is accessible to the interface 304.

The JTAG circuit 301 and downstream circuit 302 are similar to those described in FIG. 1. However, the downstream circuit 302 has an additional output pin connected by the interconnect 309 to an input pin of the JTAG circuit 301. The input pin connected to the interconnect 309 is coupled to the input BSC 313. To accommodate the additional output pin, two loopbacks, loopback 308 and loopback 312 are included in the downstream circuit 302. The loopback 308 connects the input pin of the downstream circuit 302 connected to interconnect 306 to the output pin of the downstream circuit 302 connected to interconnect 307. The loopback 312 connects the input pin of the downstream circuit 302 connected to interconnect 306 to the output pin of the downstream circuit 302 connected to interconnect 309.

The loopbacks 308 and 312 may be independently activated using the control register 305. The value of the control value 305 may be changed using the interface 304 as described in FIG. 1. The value of the control register 305 should be set so that only one of the loopbacks 308 and 312 is activated at a given time. For example, the control register 305 may consist of two bits. A transistor coupled to receive the first bit of the control register 305 may be in line with loopback 308 and a transistor coupled to receive the second bit of the control register 305 may be in line with loopback 312. Setting the value of the control register 305 to “10” would activate loopback 308 and deactivate loopback 312 and setting the value to “01” would do the opposite. Setting the value to “00” would deactivate both loopbacks 308 and 312 and allow the downstream circuit 302 to function normally. As another example, a demultiplexer connected to the control register 305 may be used, and the control register 305 value may be set according to the demultiplexer configuration to send the input test value to the desired loopback or the core logic of the downstream circuit 302.

During JTAG testing, the control register 305 may be set so that only loopback 308 is activated. During this testing, interconnects 306 and 307 are tested while interconnect 309 is not. Once the test has been completed, the control register 305 may be set so that loopback 308 is deactivated and loopback 312 is activated. After activating loopback 312 for testing, the JTAG test may be performed again. During this test, interconnects 306 and 309 are tested while interconnect 307 is not.

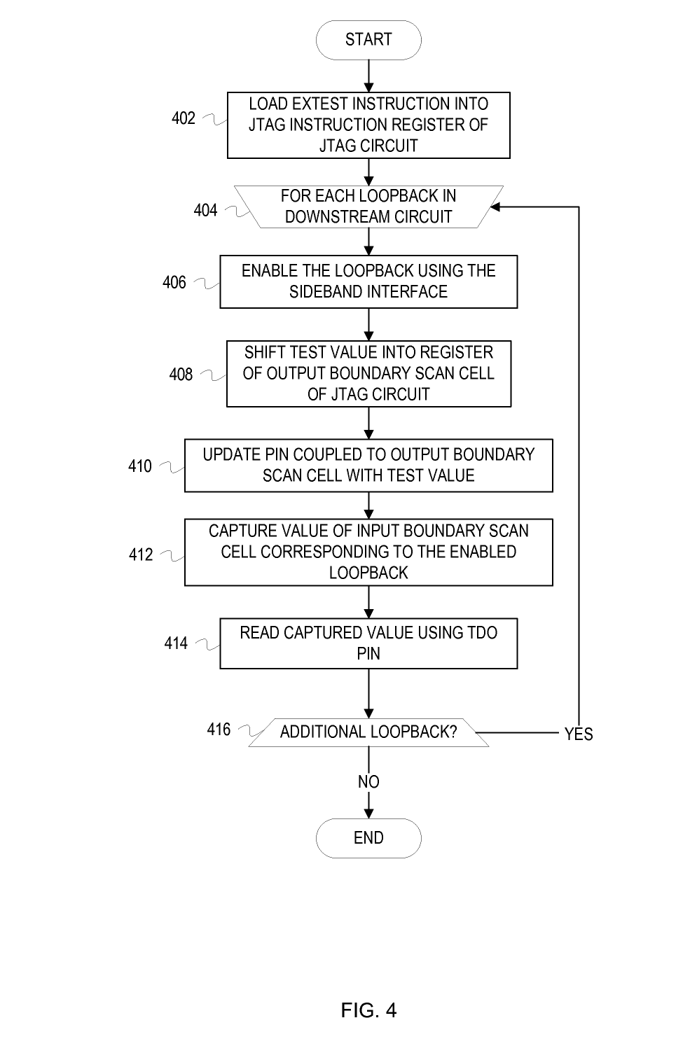

FIG. 4 depicts a flow diagram illustrating example operations for performing a JTAG test using multiple loopbacks in a non-JTAG device.

At block 402, the EXTEST JTAG instruction is loaded into a JTAG instruction register of a JTAG circuit. The EXTEST instruction is loaded similarly to block 202 of FIG. 2. Once the EXTEST instruction has been loaded, control then flows to block 404.

At block 404, a loop in which each loopback is independently activated for testing begins. For example, if a downstream circuit includes three loopbacks, during the first iteration of the loop only the first loopback would be activated; during the second iteration only the second loopback would be activated; and during the third iteration only the third loopback would be activated.

At block 406, the selected loopback is activated using a serial bus interface. The selected loopback may be independently activated as described in FIG. 3. Once the selected loopback has been activated, control then flows to block 408.

At block 408, a test value is shifted into the register of the output BSC of the JTAG circuit. The test value is shifted into the register of the output BSC as described at block 206 of FIG. 2. The test value should be shifted into the register of the BSC corresponding to the currently activated loopback. After the test value has been shifted into the appropriate register, control then flows to block 410.

At block 410, the pin of the JTAG circuit coupled to the output BSC is updated with the test value. The pin may be updated with the test value as described in block 208 of FIG. 2. Once updated, the pin coupled to the output BSC drives the test value that was shifted into the output BSC register. Once the pin has been updated with the test value, control then flows to block 412.

At block 412, the value at an input pin of the JTAG circuit is captured using an input boundary scan cell. Once a test value is driven from an output BSC as described at block 410, the test value will transmit through an interconnect connecting the JTAG circuit and the downstream circuit, transmit through the activated loopback in the downstream circuit, and return through another interconnect to an input pin of the JTAG circuit. The transmitted test value at the input pin may be captured by the input BSC coupled to the pin as described in block 210 of FIG. 2. Once the test value has been captured, control then flows to block 414.

At block 414, the captured test value is read through the TDO pin. The captured test value is read as described in block 212 of FIG. 2. Once the captured test value has been read, the captured test value may be compared to the originally transmitted test value to determine whether any fault exists. After the captured test value has been read, control then flows to block 416.

At block 416, it is determined whether there is an additional loopback that has not been tested. If there is an additional loopback, control then flows to block 404. If all loopbacks have been independently activated for testing, the process ends.

In the descriptions above, the JTAG circuit and the downstream circuit are assumed to each have at least one input and output in communication and available. In some instances, a JTAG circuit may only output data to the downstream circuit and may not have an available input pin to receive data from the downstream circuit. In such an instance, returning a received test value through a loopback directly to the JTAG circuit is not possible. When the JTAG circuit and the downstream circuit do not have both input and output communications, another downstream circuit in communication with both circuits may be used. By using loopbacks in both downstream circuits, test values transmitted by the JTAG circuit may be returned to the JTAG circuit using loopbacks in two or more downstream circuits as described below.

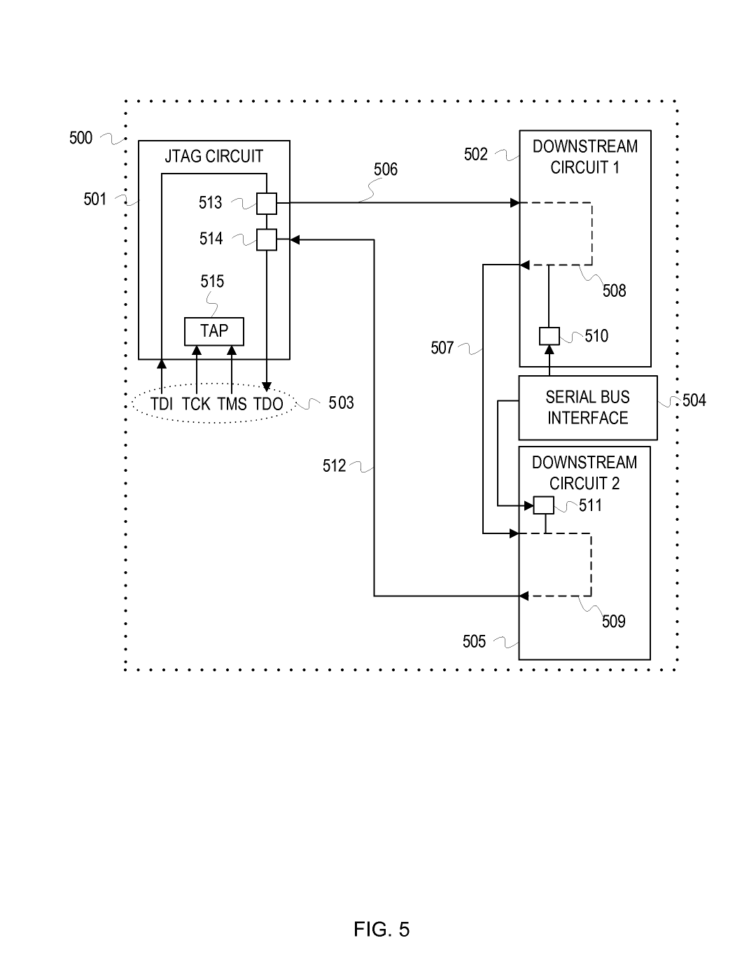

FIG. 5 is a conceptual diagram illustrating the testing of interconnects between multiple integrated circuits using loopbacks. FIG. 5 depicts a printed circuit board 500 that includes a JTAG circuit 501, a downstream circuit 1 502, a downstream circuit 2 505, and a serial bus interface 504 (“interface 504”). The JTAG circuit 501 includes circuitry to conduct JTAG testing including the JTAG pins 503: TDI, TCK, TMS and TDO. The TCK and TMS pins of the JTAG pins 503 are connected to a TAP controller 515. The JTAG circuit 501 also includes boundary scan architecture including output BSC 513 and input BSC 514. The JTAG circuit 501 and the downstream circuit 1 502 are connected by an interconnect 506. The downstream circuit 1 502 and downstream circuit 2 505 are connected by an interconnect 507. The downstream circuit 2 505 and the JTAG circuit 501 are connected by an interconnect 512. The downstream circuit 1 502 includes a loopback 508 and a control register 510 that is accessible to the interface 504. The downstream circuit 2 505 includes a loopback 509 and a control register 511 that is accessible to the interface 504.

The JTAG circuit 501 and downstream circuit 1 502 are similar to those described in FIG. 1. However, the downstream circuit 1 502 has no output pin to return test values to the JTAG circuit 501. In order to return the test value, downstream circuit 2 505 is used. A path is created to return a test value using the interconnects 506, 507, and 512 and the loopbacks 508 and 509. The loopback 508 connects the input pin of the downstream circuit 1 502 connected to interconnect 506 to the output pin connected to interconnect 507. The loopback 512 connects the input pin of the downstream circuit 2 505 connected to interconnect 507 to the output pin connected to interconnect 512.

The loopbacks 508 and 509 are activated using the interface 504 and the control registers 510 and 511. The interface 504 is connected to both control registers 510 and 511, and can set the values of the control registers 510 and 511 to activate the loopbacks 508 and 509 using techniques described above in FIG. 1. The loopbacks 508 and 509 should both be activated to complete a return path for a test value. During JTAG testing, a test value is transmitted by the output BSC 513 through the interconnects 506, 507, and 512 and the activated loopbacks 508 and 509. The test value is received at the input pin coupled to the input BSC 514.

FIG. 5 depicts transmitting a test value using loopbacks in two downstream circuits. Similar techniques may be used to transmit a test value through three or more downstream circuits using loopbacks. Additionally, multiple unique paths to transmit a test value may be created by selectively activating and deactivating specific loopbacks. Testing as many path combinations as possible provides a more complete testing of the interconnects in a board.

Despite the utility of JTAG testing in accordance with the IEEE 1149.1 standard, that standard was not designed for AC-coupled differential pairs. AC-coupled differential pairs are employed in high speed digital paths which have transfer rates of at least 1 GB per second. Thus, the IEEE 1149.6 standard was designed for testing of circuits with AC-coupled differential pairs (AC-JTAG testing). With AC-JTAG testing, a JTAG circuit produces pulses that pass through a DC-blocking capacitors of the differential pair.

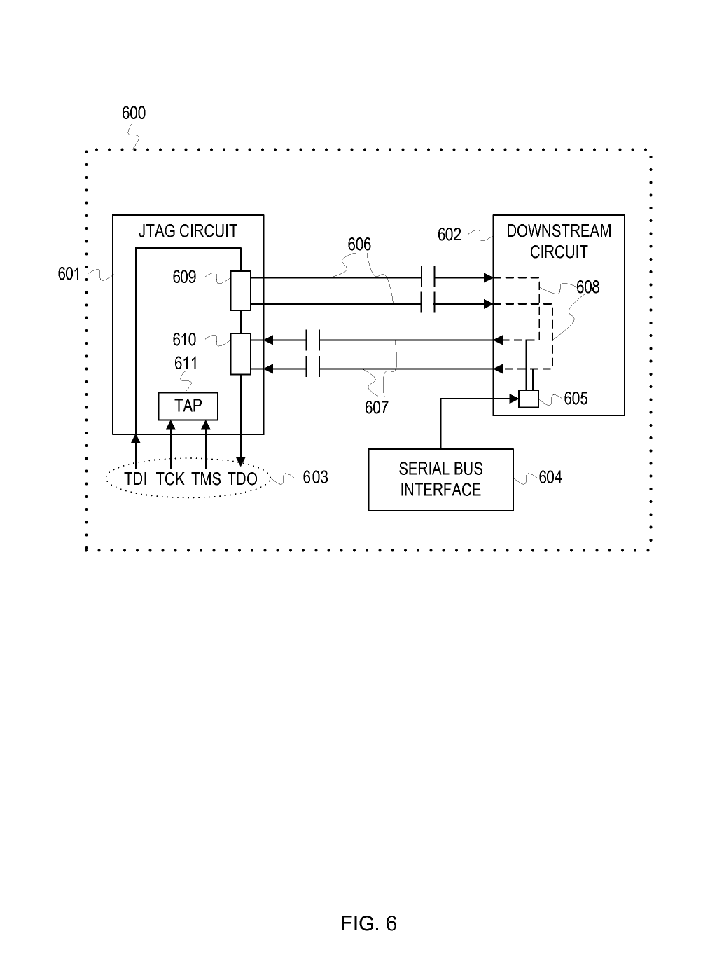

FIG. 6 is a conceptual diagram illustrating the differential signaling testing of interconnects between integrated circuits using loopbacks. FIG. 6 depicts a printed circuit board 600 that includes a JTAG circuit 601, a downstream circuit 602, and a serial bus interface 604 (“interface 604”). The JTAG circuit 601 is a JTAG capable circuit and includes JTAG pins 603. The JTAG pins 603 include the typical four pins for JTAG testing, TDI, TCK, TMS and TDO, but additional pins in accordance with other JTAG pin configurations may be included, such as the test reset pin, TRST. The TCK and TMS pins of the JTAG pins 603 are connected to a TAP controller 611. The TAP controller 611 includes a state machine and an instruction register, not depicted, in accordance with the IEEE 1149.6 standard. The TAP controller 611 may also include additional circuitry such as a bypass register. The state machine of the TAP controller 611 may be controlled using the TCK and TMS pins of the JTAG pins 603. The JTAG circuit 601 also includes boundary scan architecture including multiple input and output BSCs. FIG. 6 only depicts output BSC 609 and input BSC 610. A circuit with boundary scan architecture generally includes a BSC coupled to each pin of the circuit and connected in series between the TDI and TDO pins of the JTAG pins 603. In the case of differential signaling pairs, a single BSC is coupled to two pins. The output BSC 609 and input BSC 610 include the typical circuitry of input and output boundary scan cells for use with differential signaling pairs. For example, the output BSC 109 includes a register for storage of a test value and circuitry for driving a test value. The input BSC 110 includes a register to capture incoming test values. The JTAG circuit 601 and the downstream circuit 602 are connected by differential signaling pairs 606 and 607. The downstream circuit 602 includes loopbacks 608 and a control register 605 that is accessible to the interface 604.

The JTAG circuit 601 and the downstream circuit 602 communicate through the differential signaling pairs 606 and 607. The differential signaling pairs 606 and 607 are interconnects that connect four pins of the JTAG circuit 601 to four pins of the downstream circuit 602. Differential signaling pair 606 is coupled to the output BSC 609 and the differential signaling pair 607 is coupled to the input BSC 610 of the JTAG circuit 601. The differential signaling pairs 606 and 607 are connected through the loopbacks 608 of the downstream circuit 602 when the loopbacks 608 are activated.

The loopbacks 608 may be activated using the interface 604 to set the control register 605 to an appropriate value. Since differential signaling involves two signals, the loopbacks 608 should be activated and deactivated in coordination. For example, the paths of loopbacks 608 may each contain a transistor coupled to the control register 605 causing the transistors to act like switches. Setting the control register 105 to a value “0” would turn the transistors “off”, deactivate both of the loopbacks 608, and allow the downstream circuit 602 to function normally. Setting the control register 605 to a value “1” would turn the transistors “on” and activate both of the loopbacks 608 for testing. Additionally, a demultiplexer may be used to select whether the incoming test value is sent to the core logic of the downstream circuit 602 or through the loopbacks 608.

Activating the loopbacks 608 causes test values sent from the output BSC 609 during AC-JTAG testing to bypass the downstream circuit 602 core logic. A test value is driven by output BSC 609, across the differential signaling pair 606, through the loopbacks 608, across the differential signaling pair 607, and received at the input BSC 610. Therefore, assuming the differential signaling pairs 606 and 607 are functioning properly, the same test value transmitted by the output BSC 609 will be received by the input BSC 610. If the test value is different, then the difference indicates that at least one of the differential signaling pair 606 and the differential signaling pair 607 contains a fault such as a short, an open, or other fault.

Testing software may be designed to selectively activate and deactivate loopbacks in conjunction with JTAG testing software. The testing software may connect to a serial bus interface to perform the functions described in the illustrations above and set the control registers to the appropriate values. For example, during testing as described in FIG. 4, the testing software may deactivate a loopback and activate another loopback upon each iteration of the loop beginning at block 404.

The Figures above depict loopbacks that are integrated into circuits. Loopbacks may also be integrated into a printed circuit board for either of single ended signaling or differential signaling. The same testing techniques described above may be utilized regardless of whether the loopback is part of the board or the integrated circuit.

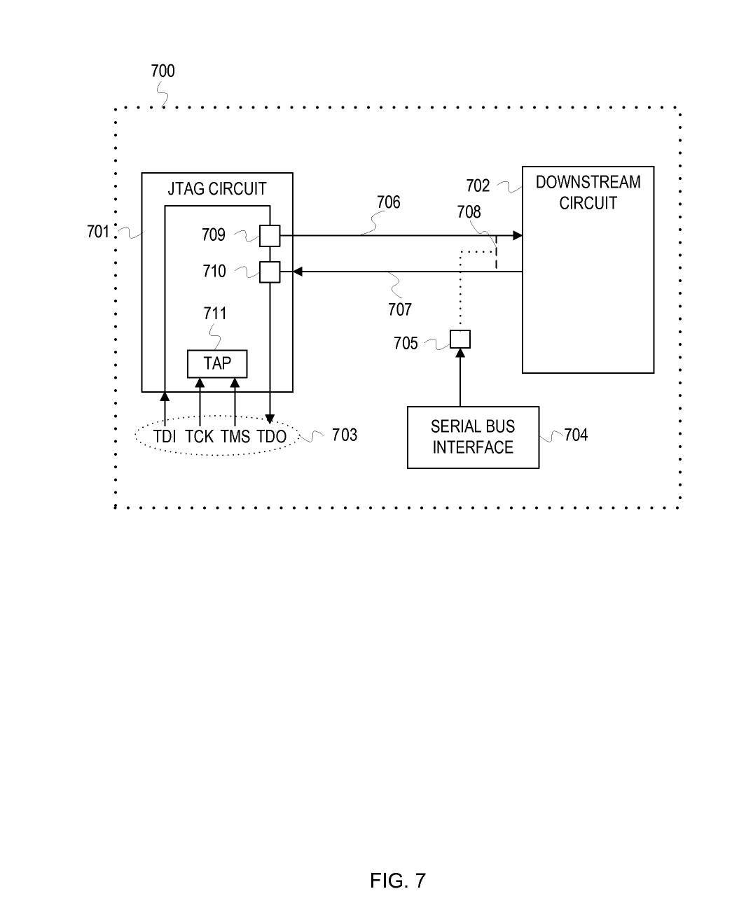

FIG. 7 is a conceptual diagram illustrating the testing of interconnects between integrated circuits using a loopback integrated in a printed circuit board. FIG. 7 depicts a printed circuit board 700 (“board 700”) that includes a JTAG circuit 701, a downstream circuit 702, and a serial bus interface 704 (“interface 704”). The board 700 also includes a loopback 708 and a control register 705 that is accessible to the interface 704. The JTAG circuit 701 is a JTAG capable circuit including JTAG pins 703: TDI, TCK, TMS and TDO. The TCK and TMS pins of the JTAG pins 703 are connected to a TAP controller 711. The JTAG circuit 701 also includes boundary scan architecture including multiple input and output BSCs. As with FIG. 1, FIG. 7 only depicts output BSC 709 and input BSC 710. The JTAG circuit 701 and the downstream circuit 702 are connected by interconnects 706 and 707.

The loopback 708, when activated, allows for the interconnects between control circuit 701 and downstream circuit 702 to be tested without requiring a loopback to be integrated in the downstream circuit 702. The loopback 708 may be located anywhere along the path of interconnects 706 and 707. However, placing the loopback 708 immediately adjacent to the downstream circuit 702 allows a test value to travel the full length of the interconnects 706 and 707.

The loopback 708 may be activated using the control register 705 with the same techniques described above in FIG. 1. Also, the loopback 708 may include a transistor that acts like a switch or a demultiplexer.

For a board with AC-coupled differential pairs, loopbacks integrated into the board are located after the DC-blocking capacitors of the differential pairs.

The above example illustrations describe details that are provided to aid in understanding the disclosure. The scope of the claims, however, should not be limited to these example illustrations. For instance, a general purpose input/output (GPIO) interface can be used instead of a serial interface to control loopbacks. As another example, wireless inter-chip communication can be used to control a loopback. A transmitter can transmit control data to a control register coupled to a switch of the loopback. A transmitter can also transmit control data to the demultiplexer or transistor switch of the loopback.

As will be appreciated, aspects of the disclosure may be embodied as a system, method or program code/instructions stored in one or more machine-readable media. Accordingly, aspects may take the form of hardware, software (including firmware, resident software, micro-code, etc.), or a combination of software and hardware aspects that may all generally be referred to herein as a “circuit,” “module” or “system.” The functionality presented as individual modules/units in the example illustrations can be organized differently in accordance with any one of platform (operating system and/or hardware), application ecosystem, interfaces, programmer preferences, programming language, administrator preferences, etc.

Any combination of one or more machine readable medium(s) may be utilized. The machine readable medium may be a machine readable signal medium or a machine readable storage medium. A machine readable storage medium may be, for example, but not limited to, a system, apparatus, or device, that employs any one of or combination of electronic, magnetic, optical, electromagnetic, infrared, or semiconductor technology to store program code. More specific examples (a non-exhaustive list) of the machine readable storage medium would include the following: a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a machine readable storage medium may be any tangible medium that can contain, or store a program for use by or in connection with an instruction execution system, apparatus, or device. A machine readable storage medium is not a machine readable signal medium.

A machine readable signal medium may include a propagated data signal with machine readable program code embodied therein, for example, in baseband or as part of a carrier wave. Such a propagated signal may take any of a variety of forms, including, but not limited to, electro-magnetic, optical, or any suitable combination thereof. A machine readable signal medium may be any machine readable medium that is not a machine readable storage medium and that can communicate, propagate, or transport a program for use by or in connection with an instruction execution system, apparatus, or device.

Program code embodied on a machine readable medium may be transmitted using any appropriate medium, including but not limited to wireless, wireline, optical fiber cable, RF, etc., or any suitable combination of the foregoing.

Program code for carrying out operations for aspects of the disclosure may be written in any combination of one or more programming languages, including an object oriented programming language such as the Java® programming language, C++ or the like; a dynamic programming language such as Python; a scripting language such as Perl programming language or PowerShell script language; and conventional procedural programming languages, such as the “C” programming language or similar programming languages. The program code may execute entirely on a stand-alone machine, may execute in a distributed manner across multiple machines, and may execute on one machine while providing results and or accepting input on another machine.

Aspects of this disclosure are described with reference to flowchart illustrations and/or block diagrams. It will be understood that each block of the flowchart illustrations and/or block diagrams, and combinations of blocks in the flowchart illustrations and/or block diagrams, can be implemented by program code. The program code may be provided to a processor of a general purpose computer, special purpose computer, or other programmable machine or apparatus.

The program code/instructions may also be stored in a machine readable medium that can direct a machine to function in a particular manner, such that the instructions stored in the machine readable medium produce an article of manufacture including instructions which implement the function/act specified in the flowchart and/or block diagram block or blocks.

While aspects are described with reference to various exploitations, it will be understood that these aspects are illustrative and that the scope of the disclosure is not limited to them. In general, techniques for selectively activating loopbacks to facilitate JTAG testing as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the exemplary configurations may be implemented as a combined structure or component. Similarly, structures and functionality presented as a single component may be implemented as separate components. These and other variations, modifications, additions, and improvements may fall within the scope of the disclosure.

Use of the phrase “at least one of . . . or” should not be construed to be exclusive. For instance, the phrase “X comprises at least one of A, B, or C” does not mean that X comprises only one of {A, B, C}; it does not mean that X comprises only one instance of each of {A, B, C}, even if any one of {A, B, C} is a category or sub-category; and it does not mean that an additional element cannot be added to the non-exclusive set (i.e., X can comprise {A, B, Z}).

What is claimed is:

1. A method of testing interconnects with a first integrated circuit that lacks boundary scan testing standard compliant circuitry, the method comprising:
activating a loopback that couples a first interconnect to a second interconnect, wherein the first interconnect and the second interconnect connect the first integrated circuit and a second integrated circuit;
transmitting a first value from the second integrated circuit to the first integrated circuit over the first interconnect, wherein the first value is transmitted in accordance with the boundary scan testing standard, wherein the first value travels through the loopback that was activated;
capturing, in a boundary scan cell of the second integrated circuit, a second value received at the second integrated circuit over the second interconnect; and
determining whether the first value and the second value are the same to detect malfunction of the first interconnect or the second interconnect.

2. The method of claim 1, wherein the loopback comprises a conductive path with a transistor.

3. The method of claim 2, wherein activating the loopback comprises setting a control value in a register of the first integrated circuit, wherein the register is coupled to control the transistor in accordance with the control value.

4. The method of claim 1, wherein the loopback comprises a conductive path with a demultiplexer.

5. The method of claim 4, wherein activating the loopback comprises setting a control value in a register of the first integrated circuit, wherein the register is coupled to control the demultiplexer in accordance with the control value.

6. The method of claim 1 further comprising:
in coordination with activating the loopback, activating a second loopback that couples a third interconnect to a fourth interconnect, wherein the third interconnect and the fourth interconnect connect the first integrated circuit and a second integrated circuit;
transmitting a third value from the second integrated circuit to the first integrated circuit over the third interconnect in coordination with transmitting the first value over the first interconnect, wherein the first value is transmitted in accordance with the boundary scan testing standard, wherein the first value travels through the loopback that was activated, and wherein the third value and the first value are complementary; and
capturing, in the boundary scan cell of the second integrated circuit, a fourth value received at the second integrated circuit over the fourth interconnect;
wherein determining whether the first value and the second value are the same to detect malfunction comprises determining whether a difference of the first and third value is the same as a difference of the second and fourth value to detect malfunction of at least one of the first, second, third, or fourth interconnect.

7. The method of claim 1, further comprising:
deactivating the loopback;
activating a second loopback of the first integrated circuit, wherein the second loopback connects the input pin of the first integrated circuit to a second output pin of the first integrated circuit, wherein a third interconnect connects the second output pin of the first integrated circuit to a second input pin of the second integrated circuit;
transmitting a third value from the output pin of the second integrated circuit to the input pin of the first integrated circuit;
capturing, in a second boundary scan cell of the second circuit, a fourth value received at the second input pin of the second integrated circuit; and
determining whether the third value and the fourth value are the same to determine malfunction of the first interconnect or the third interconnect.

8. A system comprising:
a first integrated circuit comprising,
core logic;
a plurality of boundary scan cells;
input pins and output pins associated with the plurality of boundary scan cells;
boundary scan test logic circuitry;
a plurality of interconnects;
a second integrated circuit connected to the first integrated circuit with at least two of the plurality of interconnects, the second integrated circuit comprising,
a first input pin coupled to a first interconnect of the plurality of interconnects, the first interconnect also connected to a first output pin of the output pins of the first integrated circuit;
a second output pin coupled to a second interconnect of the plurality of interconnects, the second interconnect also connected to a second input pin of the input pins of the first integrated circuit;
loopback circuitry that connects the first input pin to the second output pin when activated; and
a serial bus interface coupled with the loopback circuitry to control activation of the loopback circuitry.

9. The system of claim 8, wherein the loopback circuitry comprises a conductive path with a transistor.

10. The system of claim 9, wherein the loopback circuitry comprises a register connected to the serial bus interface, wherein the register is coupled to control the transistor in accordance with a control value.

11. The system of claim 8, wherein the loopback comprises a conductive path with a demultiplexer.

12. The system of claim 11, wherein the loopback circuitry comprises a register connected to the serial bus interface, wherein the register is coupled to control the demultiplexer in accordance with the control value.

13. The system of claim 8, further comprising a second loopback circuitry that connects the first input pin to a third output pin when activated, the third output pin coupled to a third interconnect of the plurality of interconnects, the third interconnect also connected to a third input pin of the input pins of the first integrated circuit.

14. The system of claim 13, wherein the serial bus interface is coupled with the second loopback circuitry to control activation of the second loopback circuitry.

15. A system comprising:
a first integrated circuit comprising,
first core logic;
a plurality of boundary scan cells;
a plurality of pins associated with the plurality of boundary scan cells, wherein the plurality of pins at least includes a first output pin and a first input pin;
boundary scan test logic circuitry;
a second integrated circuit comprising,
second core logic;
a second input pin;
a second output pin;
a circuit board that at least supports the first integrated circuit and the second integrated circuit, the circuit board comprising,
a first interconnect that couples the first output pin to the second input pin;
a second interconnect that couples the second output pin to the first input pin;
a loopback circuitry that connects the first interconnect to the second interconnect when activated; and
a serial bus interface coupled with the loopback circuitry to control activation of the loopback circuitry.

16. The system of claim 15, wherein:
the first integrated circuit further comprising a third output pin and a third input pin;
the second integrated circuit further comprising a fourth output pin and a fourth input pin;
the circuit board further comprising,
a third interconnect that couples the third output pin to the fourth input pin;
a fourth interconnect that couples the fourth output pin to the third input pin; and
a second loopback circuitry that connects the third interconnect to the fourth interconnect when activated.

17. The system of claim 16, wherein the serial bus interface is coupled with the second loopback circuitry to control activation of the second loopback circuitry.

18. The system of claim 15, further comprising:
the first integrated circuit further comprising a third input pin;
the second integrated circuit further comprising a third output pin;
the circuit board further comprising,
a third interconnect that couples the third output pin to the third input pin;
a second loopback circuitry that connects the first interconnect to the third interconnect when activated.

19. The system of claim 15, wherein the loopback circuitry comprises a conductive path with a transistor controlled by the serial bus interface.

20. The system of claim 15, wherein the loopback circuitry comprises a conductive path with a demultiplexer controlled by the serial bus interface.
